(19) United States
(12) Patent Application Publication
(10) Pub. No.: US 2026/0250843 A1
(43) Pub. Date: Aug. 27, 2026

(54) ATOMIC LAYER DEPOSITION APPARATUS AND ATOMIC LAYER DEPOSITION METHOD

(71) Applicant: CV Research Corporation, Funabashi-shi, Chiba (JP)

(72) Inventor: Hiroshi KAWAURA, Chiba (JP)

(21) Appl. No.: 19/489,744

(22) PCT Filed: Apr. 11, 2024
(86) PCT No.: PCT/JP2024/014724

§ 371 Date: Dec. 3, 2025

(30) Foreign Application Priority Data
Jun. 5, 2023 (JP) 2023-092608

(51) Int. Cl. C23C 16/455; C23C 16/52

(52) U.S. Cl. CPC C23C 16/45551; C23C 16/52

(57) ABSTRACT

An atomic layer deposition apparatus and an atomic layer deposition method for obtaining high-quality thin films when performing film deposition by ALD.
A substrate, which has finished a step of being reacted with a reactant at a high temperature and is mounted on a spot facing on a susceptor, is moved to another position inside a reactor by rotating a rotary table and placed in close proximity to a convex portion of a third stage while supplying an inert gas from below via a third-stage gas nozzle to a space between the spot facing and the convex portion to rapidly cool the substrate. This configuration allows ALD deposition, in which a precursor is adsorbed at a low temperature and a reaction with the reactant occurs at a high temperature, to be performed at a high speed to obtain a high-quality thin film.

### FIELD OF INVENTION

The present invention relates to an atomic layer deposition apparatus and an atomic layer deposition method used for manufacturing electronic devices such as semiconductors, flat panel displays, solar cells and light-emitting diodes.

### BACKGROUND OF INVENTION

Film deposition technologies based on atomic layer deposition (ALD) are widely used for manufacturing electronic devices such as semiconductors, flat panel displays, solar cells and light-emitting diodes.

In recent years, in particular, a double patterning technology that makes it possible to form extremely fine patterns without using very expensive extreme ultraviolet (EUV) lithography equipment has been developed, with ALD attracting attention as a key technology for this purpose. This is a technology to deposit a silicon or metal oxide film with a thickness of approximately 10 to 20 nm on a patterned organic resist film by a film deposition method with good uniformity and step coverage at a temperature of approximately 200° C. or lower to prevent degradation of the resist film.

Meanwhile, power semiconductors have become indispensable in automobiles, for which engines, brakes and other components are highly electronically controlled. With the worldwide promotion of electric vehicles (EVs), improvements in the performance of power semiconductors are essential for higher performance of EVs. As one of the methods to improve the performance of power semiconductors, Si substrates are being replaced with SiC substrates or GaN substrates, which enable high breakdown voltages and high currents. For power semiconductors using a SiC substrate or a GaN substrate, ALD is gradually being introduced for nitride films in place of chemical vapor deposition (CVD) since their film quality is particularly important. For example, for GaN devices, the formation of an aluminum nitride (AlN) layer using the ALD technology has significantly improved the channel mobility compared to devices without an aluminum nitride layer (see, for example, Non-patent document 1).

The ALD technology is also being used in many other processes, including high-k/metal gate formation, top and bottom electrode formation for DRAM capacitors using TiN or Ru, gate electrode sidewall formation using SiN and barrier seed formation in contact holes and through holes, as well as high-k dielectric and charge trap film formation for a NAND flash memory. The ALD technology is also used in ITO film formation and passivation film formation for flat panel displays, LEDs and solar cells.

For the conventional ALD, although single-wafer and batch types (see, for example, Patent document 1) are widely known, the low processing speed (number of substrates that can be processed per unit time) is often a problem, prompting various efforts to date (see, for example, Patent document 2). As one of the efforts, a rotating semi-batch ALD apparatus was developed. For the rotating semi-batch ALD apparatus, a cylindrical vacuum vessel is divided into a total of four fan-shaped subchambers consisting of two reaction gas chambers and two purge gas chambers arranged between the reaction gas chambers, with a reaction gas supply means provided above the center of each subchamber and a gas exhaust section below the two purge gas chambers. By rotating a disk-shaped table, multiple substrates to be processed on the table pass through each subchamber to perform ALD deposition (see, for example, Patent document 3).

An improved rotating semi-batch ALD apparatus with a gas curtain was developed. The gas curtain-type rotating semi-batch ALD apparatus suppresses the mixing of reaction gases by flowing a purge gas between the reaction gas supply means like a curtain (see, for example, Patent document 4).

As a film deposition apparatus using sputtering, an apparatus for depositing multiple layers on a disk-shaped workpiece transferred by a rotary transfer table with a cooling mechanism for cooling the disk-shaped workpiece has been disclosed (see, for example, Patent documents 5 and 6).

### PRIOR ART DOCUMENTS

### Patent Documents

[Patent document 1] Japanese Patent Publication No. 2004-6801.
[Patent document 2] Japanese Patent Publication No. 2014-201804.
[Patent document 3] U.S. Pat. No. 5,225,366.
[Patent document 4] U.S. Pat. No. 6,576,062.
[Patent document 5] Japanese Patent Publication No. 2005-325428.
[Patent document 6] Japanese Patent Publication No. 2020-97779.

### Non-Patent Document

[Non-patent document 1] M. Kuraguchi, Y. Kajiwara and A. Mukai, TOSHIBA REVIEW, Vol. 75, No. 6(2020 ).

### SUMMARY OF INVENTION

### Problems to be Solved by Invention

However, the ALD technologies described in Patent documents 1 through 4, which are shown as prior art, have the problem that good film quality cannot be obtained. Although a step of reacting a reactant with the substrate requires a temperature of the substrate to be raised to a specific temperature, a step of reacting a precursor with the substrate is also performed similarly at a high temperature. This will result in poor film quality because carbon produced by the decomposition of the precursor may be incorporated into the film.

The technologies described in Patent documents 5 and 6 shown as prior art relate to sputtering deposition and are not for deposition by ALD. Sputtering usually requires deposition at a low pressure of approximately 1 Pa or lower, where heat transfer by a gas hardly occurs, and thus uses complex mechanisms such as elevating and lowering the substrate for cooling. Such cooling mechanisms are not suitable for ALD, where deposition is generally performed at a pressure of several hundred Pa.

The present invention was made in view of these problems to provide an atomic layer deposition apparatus and an atomic layer deposition method for obtaining high-quality thin films when performing ALD deposition.

### Means to Solve Problems

An atomic layer deposition apparatus according to a first invention of the present application includes: a reactor; a plurality of susceptors each provided with a substrate mounting portion, a first position that controls a temperature of a substrate mounted on the substrate mounting portion at a first temperature; a second position that controls the temperature of a substrate mounted on the substrate mounting portion at a second temperature; a precursor nozzle that supplies a precursor-containing gas to the substrate mounting portion arranged in the first position; a reactant nozzle that supplies a reactant-containing gas to the substrate mounting portion arranged in the second position; and a rotary table that mounts the plurality of susceptors so that the substrate mounting portions are horizontal and rotates horizontally inside the reactor to arrange the substrate mounting portions in the first position and the second position, wherein the second temperature is higher than the first temperature.

For the atomic layer deposition apparatus according to the first invention of the present application, the first temperature is preferably 50 to 150° C., and the second temperature is preferably 250 to 700° C.

It preferably includes a third position that controls the temperature of a substrate mounted on the substrate mounting portion at a third temperature.

The third temperature is more preferably lower than the first temperature.

It preferably includes a fourth position for exchanging a substrate mounted on the substrate mounting portion with a substrate outside of the reactor.

It preferably includes a lamp unit below the second position.

It preferably includes a plasma-generating unit above the second position.

It preferably includes a first stage in close proximity to the substrate mounting portion and a temperature control mechanism that controls the first stage at a specific temperature in the first position, as well as a third stage in close proximity to the substrate mounting portion and a temperature control mechanism that controls the third stage at a specific temperature in the third position.

More preferably, it includes a first-stage gas nozzle that supplies an inert gas from below the first stage between the substrate mounting portion and the first stage in the first position, as well as a third-stage gas nozzle that supplies an inert gas from below the third stage between the substrate mounting portion and the third stage in the third position.

More preferably, a groove that serves as a flow path for the inert gas is provided on each surface of the first stage and the third stage that faces the substrate mounting portion.

A plurality of C-shaped rings that each form a horseshoe shape as a whole and are each composed of a circular ring having a cutout are preferably arranged on the rotary table concentrically with the substrate mounting portions in the first position and the second position, and upper surfaces of the plurality of C-shaped rings are preferably in close proximity to a ceiling surface of the reactor.

More preferably, it further includes a center block that fills a space between the plurality of C-shaped rings while providing a gap with respect to the plurality of C-shaped rings, and an upper surface of the center block is in close proximity to the ceiling surface of the reactor.

More preferably, it further includes an inter-position gas outlet on the rotary table outside of the center block.

It preferably includes a substrate peripheral portion gas outlet between the substrate mounting portion and the C-shaped ring.

An atomic layer deposition method according to a second invention of the present application, in a reactor including: a first position that controls a temperature of a substrate mounted on a substrate mounting portion that is horizontally arranged at a first temperature; and a second position that controls the temperature of a substrate mounted on the substrate mounting portion at a second temperature, includes: a step of moving a substrate from outside the reactor and mounting it on the substrate mounting portion; a step of supplying a precursor-containing gas to the substrate mounting portion arranged in the first position and supplying a reactant-containing gas to the substrate mounting portion arranged in the second position while exhausting the reactor; and a step of rotating a rotary table that arranges the substrate mounting portions in the first position and the second position horizontally inside the reactor, wherein the second temperature is higher than the first temperature.

For the atomic layer deposition method according to the second invention of the present application, the first temperature is preferably 50 to 150° C., and the second temperature is preferably 250 to 700° C.

This configuration can provide an atomic layer deposition apparatus and an atomic layer deposition method for obtaining high-quality thin films.

### Effects of Invention

The present invention can provide an atomic layer deposition apparatus and an atomic layer deposition method for obtaining high-quality thin films when performing film deposition by ALD.

### BRIEF DESCRIPTION OF DRAWINGS

FIG. 1 is a plan view illustrating a configuration of an atomic layer deposition apparatus according to a first embodiment of the present invention.

FIG. 2 is a perspective view and a cross-sectional view illustrating a configuration of a susceptor according to the first embodiment of the present invention.

FIG. 3 is a perspective view illustrating a configuration of a first stage according to the first embodiment of the present invention.

FIG. 4 is an exploded perspective view illustrating a configuration of a rotary table according to the first embodiment of the present invention.

FIG. 5 is a perspective view illustrating the configuration of the rotary table according to the first embodiment of the present invention.

FIG. 6 is an exploded perspective view illustrating a configuration of a reactor according to the first embodiment of the present invention.

FIG. 7 is an exploded perspective view illustrating a configuration of a lid according to the first embodiment of the present invention.

FIG. 8 is an exploded perspective view illustrating the configuration of the reactor according to the first embodiment of the present invention.

FIG. 9 is a plan view illustrating the configuration of the reactor according to the first embodiment of the present invention.

FIG. 10 is a cross-sectional view illustrating the configuration of the reactor according to the first embodiment of the present invention.

FIG. 11 is a cross-sectional view illustrating the configuration of the reactor according to the first embodiment of the present invention.

FIG. 12 is a cross-sectional view illustrating the configuration of the reactor according to the first embodiment of the present invention.

FIG. 13 is a plan view illustrating the configuration of the rotary table according to the first embodiment of the present invention.

FIG. 14 is a plan view illustrating the configuration of the reactor according to the first embodiment of the present invention.

FIG. 15 is a perspective view and a cross-sectional view illustrating the configuration of the susceptor according to the first embodiment of the present invention.

FIG. 16 is a cross-sectional view illustrating the configuration of the reactor according to the first embodiment of the present invention.

FIG. 17 is a cross-sectional view illustrating the configuration of the reactor according to the first embodiment of the present invention.

FIG. 18 is a cross-sectional view illustrating the configuration of the reactor according to the first embodiment of the present invention.

FIG. 19 is a cross-sectional view illustrating the configuration of the reactor according to the first embodiment of the present invention.

FIG. 20 is a conceptual diagram illustrating a configuration of a deposition reaction according to the first embodiment of the present invention.

FIG. 21 is a conceptual diagram illustrating the configuration of the deposition reaction according to the first embodiment of the present invention.

FIG. 22 is a perspective view and a cross-sectional view illustrating the configuration of the susceptor according to a second embodiment of the present invention.

FIG. 23 is a perspective view and a cross-sectional view illustrating the configuration of the susceptor according to a third embodiment of the present invention.

FIG. 24 is a cross-sectional view illustrating the configuration of the reactor according to a fourth embodiment of the present invention.

### DESCRIPTION OF EMBODIMENTS

The following is a description of an atomic layer deposition apparatus and an atomic layer deposition method according to the embodiments of the present invention with reference to the drawings.

### First Embodiment

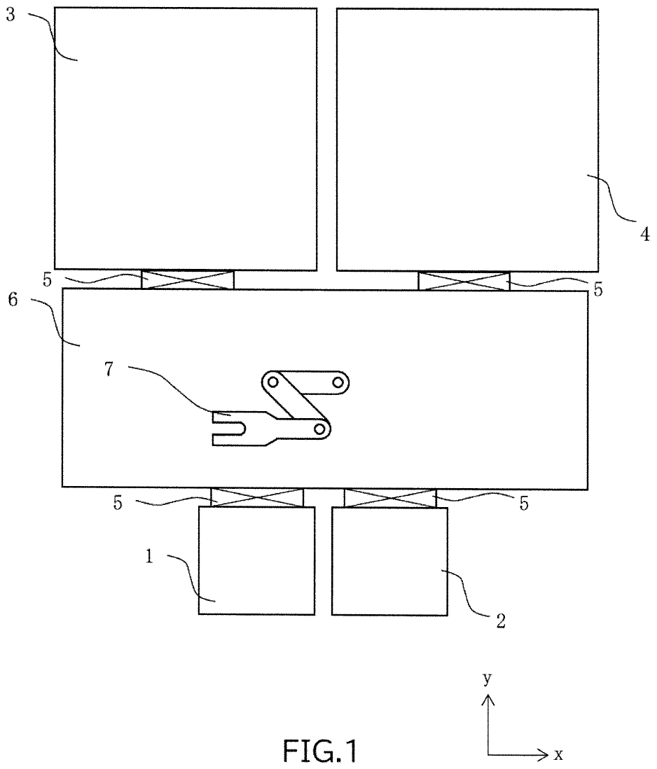

The following is a description of a first embodiment of the present invention with reference to FIGS. 1 through 21.

FIG. 1 shows a configuration of the atomic layer deposition apparatus according to the first embodiment and is a plan view of an entire apparatus, including a transport system.

The x-, y- and z-axis directions are included in each figure for easier understanding in the following descriptions. In FIG. 1, the x-axis is oriented from left to right, the y-axis from bottom to top, and the z-axis from the back of the paper to the front.

FIG. 1 shows preliminary chambers 1 and 2 and reactors 3 and 4 connected to a robot chamber 6 via gates 5. The robot chamber 6 is provided with a robot 7, which transfers substrates between the preliminary chamber 1 or 2 and the reactor 3 or 4. The preliminary chambers 1 and 2 can be load lock chambers with the reactors 3 and 4 and the robot chamber 6 operating in a vacuum at all times, or the preliminary chambers 1 and 2 and the robot chamber 6 can be atmospheric at all times with the reactors 3 and 4 being atmospheric for substrate loading/unloading and being in a vacuum for film deposition. Note that “vacuum” refers to a state of reduced pressure, meaning a pressure lower than the atmospheric pressure. The robot chamber 6 may be further provided with the ability to align a substrate.

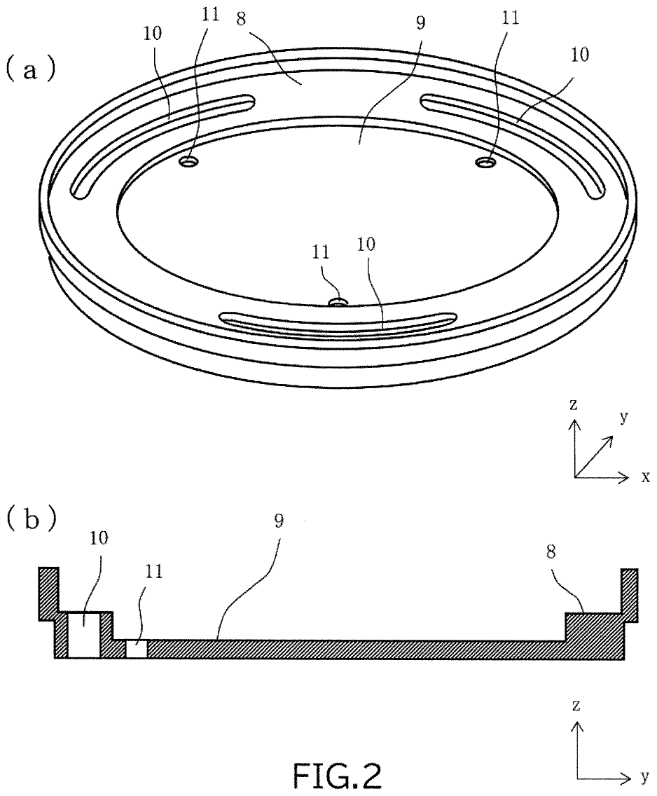

FIG. 2 is a perspective view (a) and a cross-sectional view (b) illustrating a configuration of a susceptor according to the first embodiment of the present invention, showing a state in which a substrate is not mounted on the susceptor. FIG. 2 (b) is a cross-sectional view of FIG. 2 (a) when cut along a plane parallel to the yz-plane that includes a center of the susceptor.

In FIG. 2, an overall shape of the susceptor 8 is similar to that of the substrate (circular) and is provided with a spot facing 9 that is circular in shape as a substrate mounting portion. Three slits 10 are provided beyond a periphery of the spot facing 9 as gas outlets beyond a periphery of the substrate, and three pin holes 11 are provided near an edge of the spot facing 9 for guiding lift pins when transferring a substrate. Both the slits 10 and the pin holes 11 are arranged at equal intervals along the circumferential direction. The material for the susceptor 8 is preferably one that has high heat resistance and high thermal conductivity with little deformation or deterioration, such as silicon carbide.

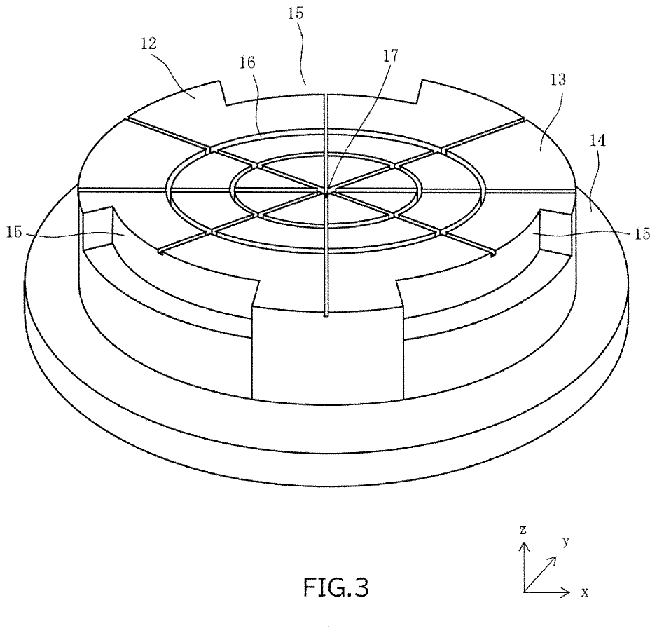

FIG. 3 is a perspective view illustrating a configuration of a first stage according to the first embodiment of the present invention. In FIG. 3, the first stage 12 consists of a convex portion 13, which forms a cylinder as a whole, and a bottom portion 14, which is composed of a cylinder with a larger diameter than the convex portion 13. Three peripheral portions of an upper surface of the convex portion 13 are notched to form stepped portions 15. The three stepped portions 15 are arranged at equal intervals along the circumferential direction. The upper surface of the convex portion 13 is provided with grooves 16 that serve as flow paths for an inert gas. In a center of the first stage 12, a first-stage gas nozzle 17 is provided for supplying the inert gas from below.

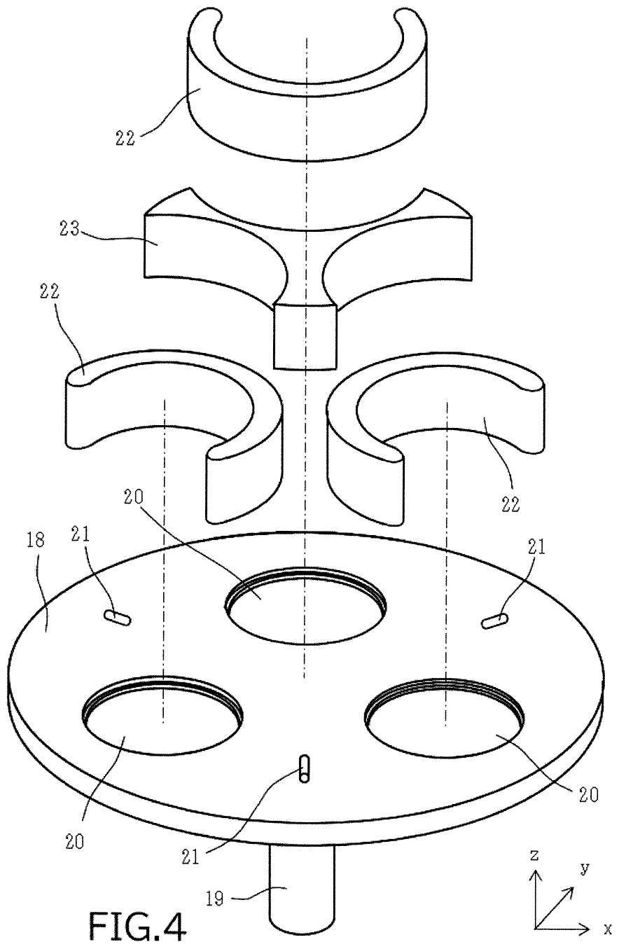

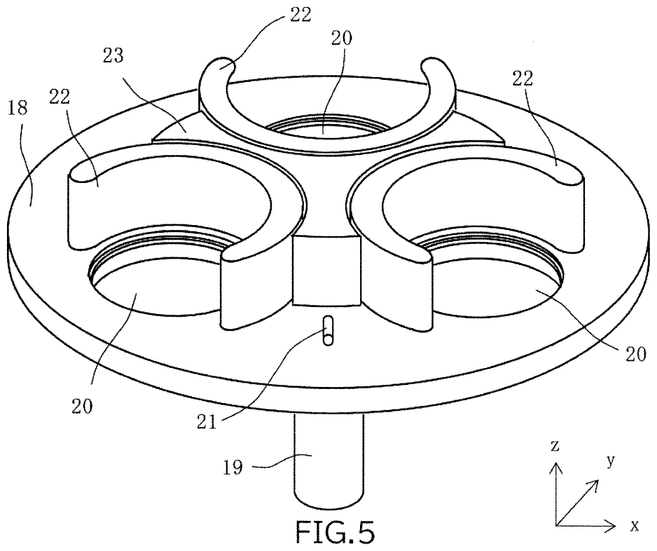

FIG. 4 is an exploded perspective view illustrating a configuration of a rotary table according to the first embodiment of the present invention. FIG. 5 is a perspective view illustrating the configuration of the rotary table according to the first embodiment of the present invention, showing the state after assembling the components shown in FIG. 4.

In FIGS. 4 and 5, the rotary table 18 is provided with a shaft 19 as an axis of rotation, three susceptor holders 20 (through-holes) for mounting three susceptors 8 and three inter-position gas outlets 21. Each of the three inter-position gas outlets 21 is arranged in a middle position between two of the three susceptor holders 20. Three C-shaped rings 22 that each form a horseshoe shape as a whole and are each composed of a circular ring having a cutout are arranged on the rotary table 18, concentrically with the susceptor holder 20. The cutout of the circular part of the C-shaped ring 22 is arranged so that it faces outward from the rotary table 18. A center block 23 that fills a space between the three C-shaped rings while providing a gap with respect to two of the three C-shaped rings is provided. The configuration includes the inter-position gas outlets 21 on the rotary table 18 outside of the center block 23.

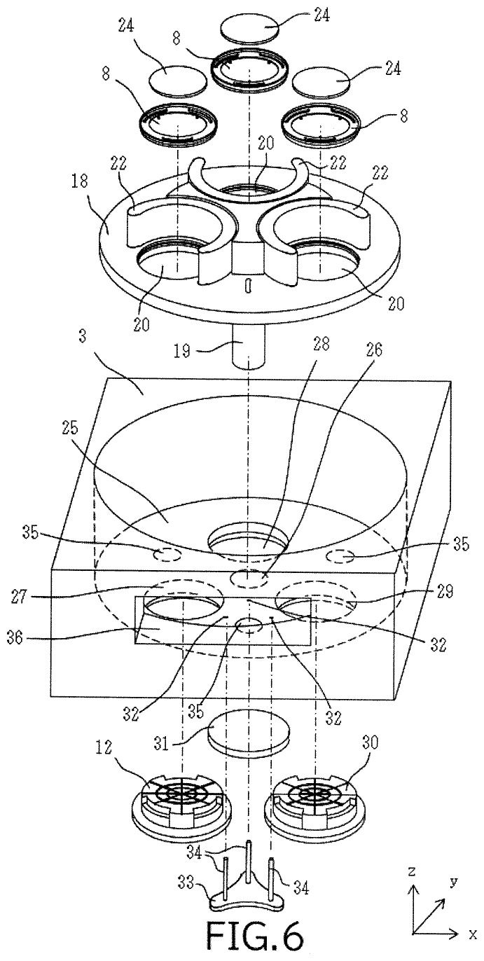

FIG. 6 is an exploded perspective view illustrating a configuration of the reactor according to the first embodiment of the present invention. In FIG. 6, a total of three substrates 24 are each mounted on the spot facing of a respective one of the three susceptors 8. The three susceptors 8 are fitted into the three susceptor holders 20. In other words, the three C-shaped rings 22 are arranged concentrically with the spot facings as the substrate mounting portions in a first position, a second position and a third position on the rotary table 18. The reactor 3 has an outer shape of a rectangle with a cylindrical interior space. The shaft 19 is inserted into a shaft hole 26 in a bottom face 25 of the reactor 3. A first position bottom hole 27, a second position bottom hole 28 and a third position bottom hole 29 are arranged at equal intervals along the circumferential direction on the bottom face 25 of the reactor 3. The convex portion of the first stage 12 is inserted into the first position bottom hole 27 from below, and the convex portion of a third stage 30 is inserted into the third position bottom hole 29 from below. The third stage 30 has a configuration similar to the first stage 12. A quartz glass window 31 is inserted into the second position bottom hole 28 from below. The bottom face 25 of the reactor 3 is further provided with three pin holes 32 for guiding the lift pins, into which three lift pins 34 fixed to a lift pin holder 33 are inserted. Each of three gas exhaust ports 35 is provided in the bottom face 25 of the reactor 3 in a middle position between two of the first position bottom hole 27, the second position bottom hole 28 and the third position bottom hole 29. A gate opening 36 for exchanging the substrates 24 is provided on a side of the reactor 3.

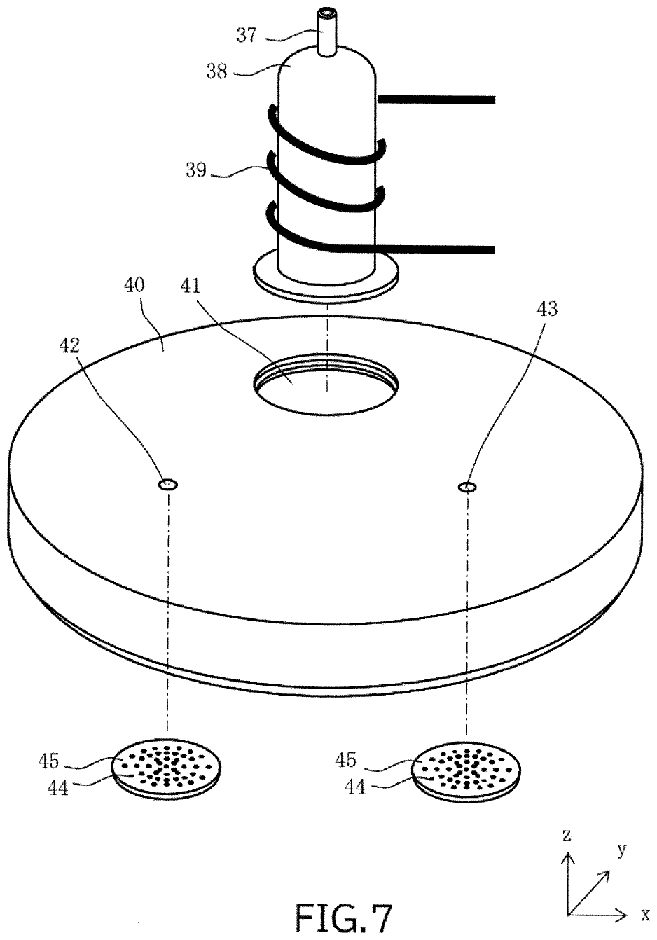

FIG. 7 is an exploded perspective view illustrating a configuration of a lid according to the first embodiment of the present invention. In FIG. 7, a coil 39 is wound around a quartz tube 38 provided with a gas inlet 37 at its uppermost portion, which forms a plasma-generating unit to be arranged above the second position. A bottom portion of the quartz tube 38 is fitted into an opening 41 provided in the lid 40 at a position corresponding to immediately above the second position. A gas introduction hole 42 and a gas introduction hole 43 are provided in the lid 40 at a position corresponding to immediately above the first position and immediately above the third position, respectively, and two shower plates 45 provided with numerous shower holes 44 are fitted from below.

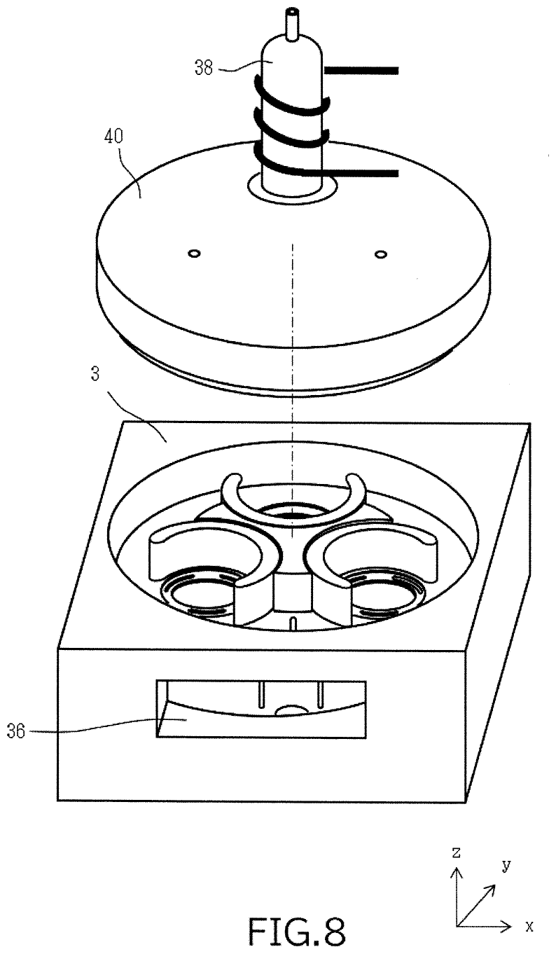

FIG. 8 is an exploded perspective view illustrating the configuration of the reactor according to the first embodiment of the present invention. The lid 40, into which the quartz tube 38 is fitted, is fitted onto the reactor 3.

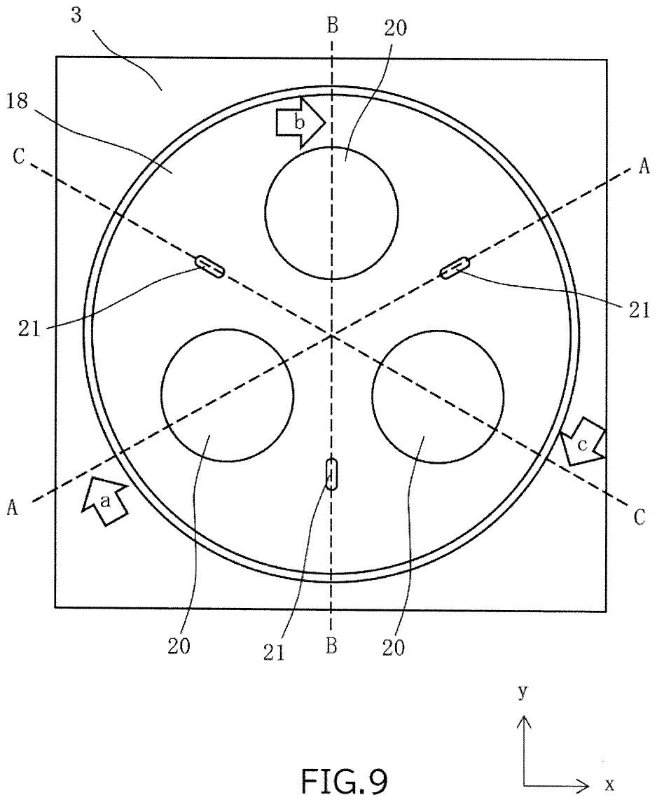

FIG. 9 is a plan view illustrating the configuration of the reactor according to the first embodiment of the present invention, with the reactor 3 viewed from above. For simplicity, only major components are shown.

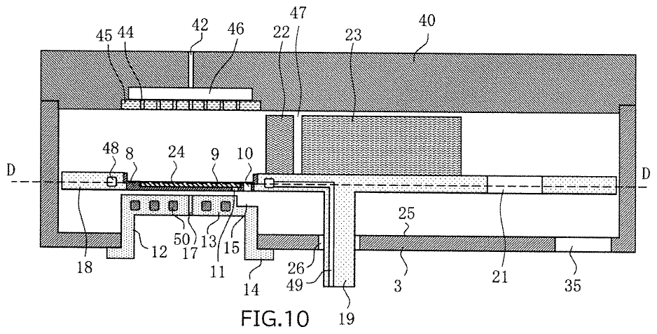

FIG. 10 is a cross-sectional view illustrating the configuration of the reactor according to the first embodiment of the present invention, viewed in a direction of arrow a in cross section A-A that is perpendicular to the xy-plane and passes through a center of the first position in FIG. 9.

In FIG. 10, the substrate 24 is mounted on the spot facing 9 as the substrate mounting portion on the susceptor 8, which is horizontally arranged. In this figure, the substrate 24 is in the first position. In the reactor 3, the slit 10 is provided as the gas outlet beyond the periphery of the substrate between the spot facing 9 and the C-shaped ring 22, and the pin hole 11 is provided near the edge of the spot facing 9 for guiding the lift pin when transferring a substrate. The first stage 12, which is in close proximity to the spot facing 9, consists of the convex portion 13 and the bottom portion 14, which has a larger diameter than the convex portion 13. The peripheral portion of the upper surface of the convex portion 13 is notched to form the stepped portion 15. In the center of the first stage 12, the first-stage gas nozzle 17 is provided for supplying the inert gas from below. The rotary table 18 is provided with the shaft 19 as the axis of rotation and the inter-position gas outlet 21. The C-shaped ring 22 is arranged on the rotary table 18, an upper surface of which is in close proximity to a ceiling surface of the reactor 3. The center block 23 is provided while providing the gap 47 with respect to the C-shaped ring 22, with its upper surface in close proximity to the ceiling surface of the reactor 3. The shaft 19 is inserted into the shaft hole 26 in the bottom face 25 of the reactor 3. The gas exhaust port 35 is provided in the bottom face 25 of the reactor 3.

The lid 40 is provided with the gas introduction hole 42, and the shower plate 45 provided with the numerous shower holes 44 as a precursor nozzle is fitted from below, configuring a precursor-containing gas supply manifold 46. To prevent liquefaction of a precursor, a portion that is to be in contact with a precursor-containing gas is preferably heated, for which a temperature control mechanism (fluid flow path, resistance heater, or the like) may be provided in the lid 40 and the shower plate 45. In this case, a temperature of the lid 40 and the shower plate 45 is preferably controlled at approximately 40 to 150° C., typically at 80° C.

A refrigerant flow path 48 is provided in the rotary table 18 around the susceptor holder 20 (the through-hole into which the susceptor 8 is fitted). A refrigerant is supplied to the refrigerant flow path 48 from a refrigerant inlet pipe 49. For the purpose of controlling a temperature of the substrate 24 at a first temperature, a temperature control mechanism 50 is provided inside the convex portion 13 of the first stage 12 to control the first stage 12 at a specific temperature. The temperature control mechanism 50 may be a fluid flow path or a resistance heater.

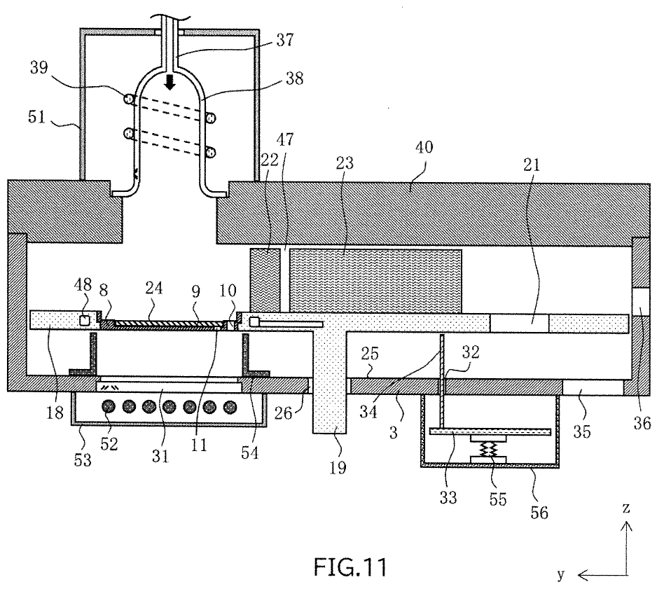

FIG. 11 is a cross-sectional view illustrating the configuration of the reactor according to the first embodiment of the present invention, viewed in a direction of arrow b in cross section B-B that is perpendicular to the xy-plane and passes through a center of the second position in FIG. 9.

In FIG. 11, the substrate 24 is mounted on the spot facing 9 as the substrate mounting portion on the susceptor 8. In this figure, the substrate 24 is in the second position. In the reactor 3, the slit 10 is provided as the gas outlet beyond the periphery of the substrate between the spot facing 9 and the C-shaped ring 22, and the pin hole 11 is provided near the edge of the spot facing 9 for guiding the lift pin when transferring a substrate. The rotary table 18 is provided with the shaft 19 as the axis of rotation and the inter-position gas outlet 21. The C-shaped ring 22 is arranged on the rotary table 18, the upper surface of which is in close proximity to the ceiling surface of the reactor 3. The center block 23 is provided while providing the gap 47 with respect to the C-shaped ring 22, with its upper surface in close proximity to the ceiling surface of the reactor 3. The shaft 19 is inserted into the shaft hole 26 in the bottom face 25 of the reactor 3. The gas exhaust port 35 is provided in the bottom face 25 of the reactor 3. The refrigerant flow path 48 is provided in the rotary table 18 around the susceptor holder 20 (the through-hole into which the susceptor 8 is fitted).

The lid 40 is provided with the plasma-generating unit that includes the quartz tube 38 provided with the gas inlet 37 as a reactant nozzle at its uppermost portion and the coil 39 wound around it. The plasma-generating unit is enclosed by a shield 51 to prevent the generation of electromagnetic noise.

The quartz glass window 31 is fitted from below the reactor 3, below which a lamp unit that includes a lamp 52 and a reflector 53 is provided. To efficiently irradiate light from the lamp 52 onto a back surface of the susceptor 8 and to reduce light irradiated onto the rotary table 18, a reflection ring 54 with a cooling mechanism, such as a refrigerant flow path, is provided. The reflection ring 54 may be provided with a through hole, which is not shown in the figure, to allow gases to be exhausted promptly. Although an example using the lamp 52 is shown here as a method for controlling the temperature of the substrate, other methods, such as a resistance heater, may also be used. The bottom face 25 of the reactor 3 is provided with the pin hole 32 for guiding the lift pin, into which the lift pin 34 fixed to the lift pin holder 33 is inserted. The lift pin holder 33 is fixed to a bellows 55 to be capable of being elevated and lowered and is housed inside a case 56. The gate opening 36 for exchanging the substrates 24 is provided on the side of the reactor 3.

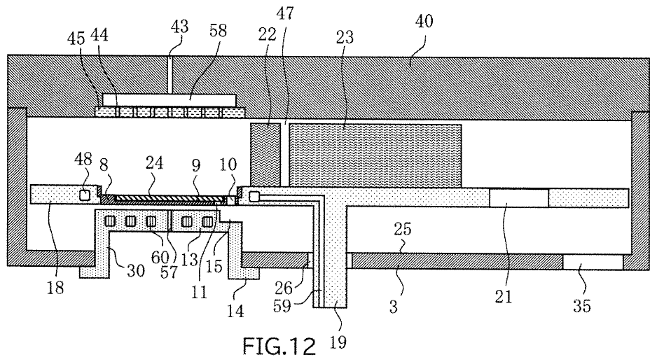

FIG. 12 is a cross-sectional view illustrating the configuration of the reactor according to the first embodiment of the present invention, viewed in a direction of arrow c in cross section C-C that is perpendicular to the xy-plane and passes through a center of the third position in FIG. 9.

In FIG. 12, the substrate 24 is mounted on the spot facing 9 as the substrate mounting portion on the susceptor 8. In this figure, the substrate 24 is in the third position. In the reactor 3, the slit 10 is provided as the gas outlet beyond the periphery of the substrate between the spot facing 9 and the C-shaped ring 22, and the pin hole 11 is provided near the edge of the spot facing 9 for guiding the lift pin when transferring a substrate. The third stage 30, which is in close proximity to the spot facing 9, consists of the convex portion 13 and the bottom portion 14, which has a larger diameter than the convex portion 13. The peripheral portion of the upper surface of the convex portion 13 is notched to form the stepped portion 15. In a center of the third stage 30, a third-stage gas nozzle 57 is provided for supplying the inert gas from below. The rotary table 18 is provided with the shaft 19 as the axis of rotation and the inter-position gas outlet 21. The C-shaped ring 22 is arranged on the rotary table 18, the upper surface of which is in close proximity to the ceiling surface of the reactor 3. The center block 23 is provided while providing the gap 47 with respect to the C-shaped ring 22, with its upper surface in close proximity to the ceiling surface of the reactor 3. The shaft 19 is inserted into the shaft hole 26 in the bottom face 25 of the reactor 3. The gas exhaust port 35 is provided in the bottom face 25 of the reactor 3.

The lid 40 is provided with the gas introduction hole 43, and the shower plate 45 provided with the numerous shower holes 44 as a purge nozzle is fitted from below, configuring a purge gas supply manifold 58.

The refrigerant flow path 48 is provided in the rotary table 18 around the susceptor holder 20 (the through-hole into which the susceptor 8 is fitted). The refrigerant supplied to the refrigerant flow path 48 is discharged from a refrigerant discharge pipe 59. For the purpose of controlling the temperature of the substrate 24 at a third temperature, a temperature control mechanism 60 is provided inside the convex portion 13 of the third stage 30 to control the third stage 30 at a specific temperature. The temperature control mechanism 60 may be a fluid flow path or a resistance heater.

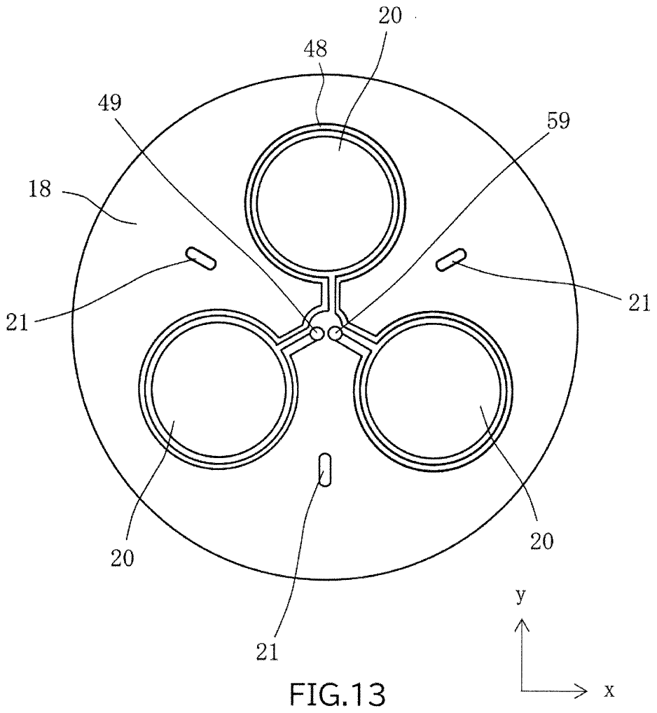

FIG. 13 is a plan view illustrating the configuration of the rotary table according to the first embodiment of the present invention, viewed in cross section D-D (horizontal plane) in FIG. 10. In FIG. 13, the rotary table 18 is provided with the three susceptor holders 20 (through-holes) for mounting the three susceptors 8 and the three inter-position gas outlets 21. The refrigerant flow path 48 is provided around the three susceptor holders 20. The refrigerant is supplied to the refrigerant flow path 48 from the refrigerant inlet pipe 49 and discharged from the refrigerant discharge pipe 59. The reason for cooling the rotary table 18 in this way is to avoid deformation due to heat. As is clear from the description below, the substrate 24 and the susceptor 8 are the hottest inside the reactor 3, thus cooling the area around the susceptor holder 20 effectively suppresses the deformation of the rotary table 18.

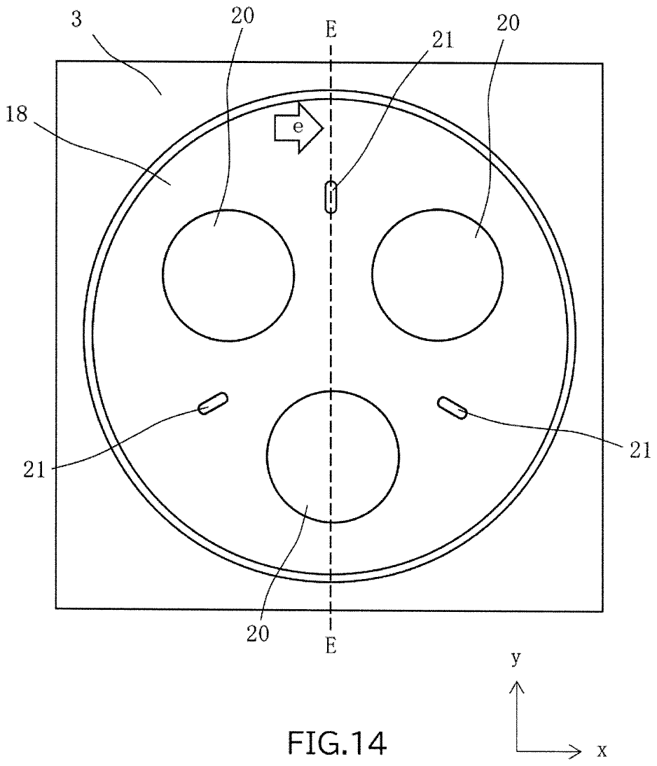

FIG. 14 is a plan view illustrating the configuration of the reactor according to the first embodiment of the present invention, with the reactor 3 viewed from above. For simplicity, only major components are shown. In FIG. 14, unlike FIG. 9, no susceptor holder is positioned at any of the positions corresponding to the first position, the second position or the third position, with only one susceptor holder positioned at a fourth position. In other words, the figure illustrates the state in which the rotary table 18 is rotated 60 degrees in FIG. 9.

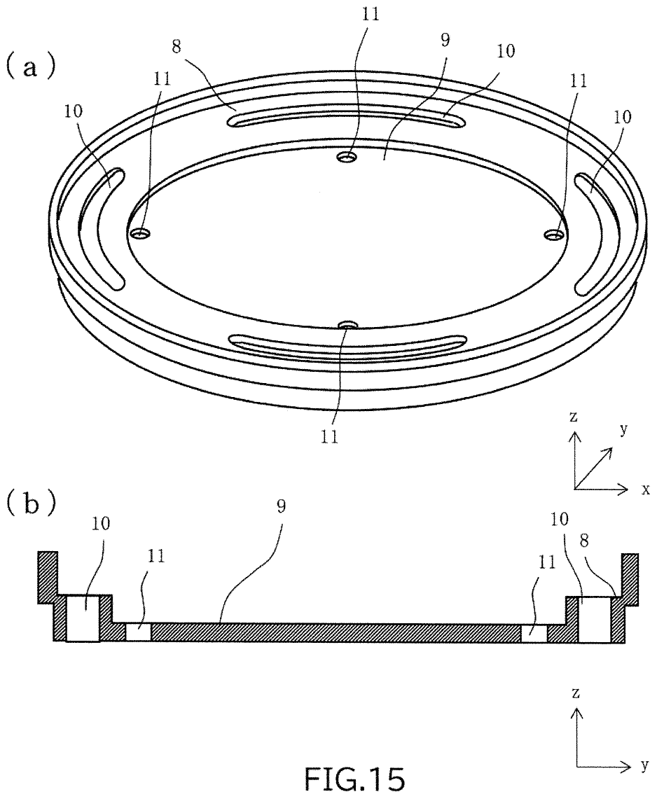

FIG. 15 is a perspective view (a) and a cross-sectional view (b) of the configuration of the susceptor according to the first embodiment of the present invention, showing the state in which a substrate is not mounted on the susceptor. FIG. 15 (b) is a cross-sectional view of FIG. 15 (a) when cut along a plane parallel to the yz-plane that includes the center of the susceptor.

In FIG. 15, the overall shape of the susceptor 8 is similar to that of the substrate (circular) and is provided with the spot facing 9 that is circular in shape as the substrate mounting portion. Four slits 10 are provided beyond the periphery of the spot facing 9 as the gas outlets beyond the periphery of the substrate, and four pin holes 11 are provided near the edge of the spot facing 9 for guiding the lift pins when transferring a substrate. Both the slits 10 and the pin holes 11 are arranged at equal intervals along the circumferential direction. The susceptor 8 shown in FIG. 15 is an example different from the susceptor 8 shown in FIG. 2 in the number and arrangement of the slits 10 and the pin holes 11. When using such a susceptor 8, the arrangement of the stepped portions 15 provided in the first stage and the third stage also needs to be changed to match the arrangement of the slits 10. In other words, four stepped portions 15 are to be provided with the slits 10 and the stepped portions 15 arranged in vertical alignment with each other.

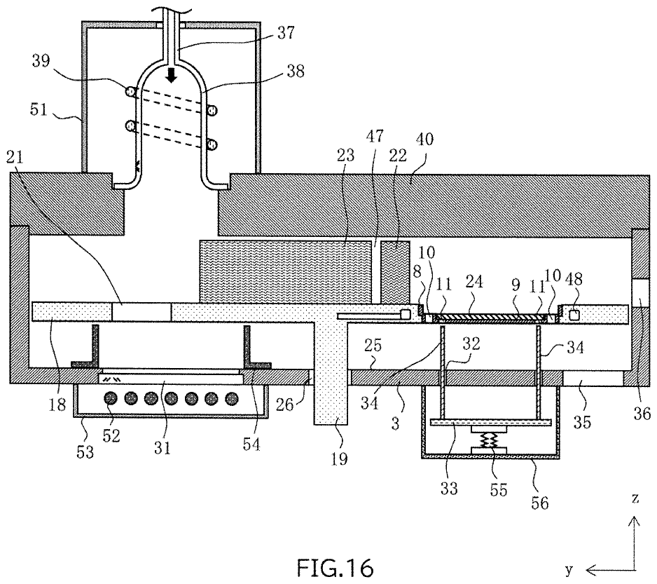

FIGS. 16 through 19 are cross-sectional views illustrating the configuration of the reactor according to the first embodiment of the present invention, viewed in a direction of arrow e in cross section E-E that is perpendicular to the xy-plane and passes through a center of the fourth position in FIG. 14. FIGS. 16 through 19 illustrate the procedure for exchanging substrates, which is described in detail below.

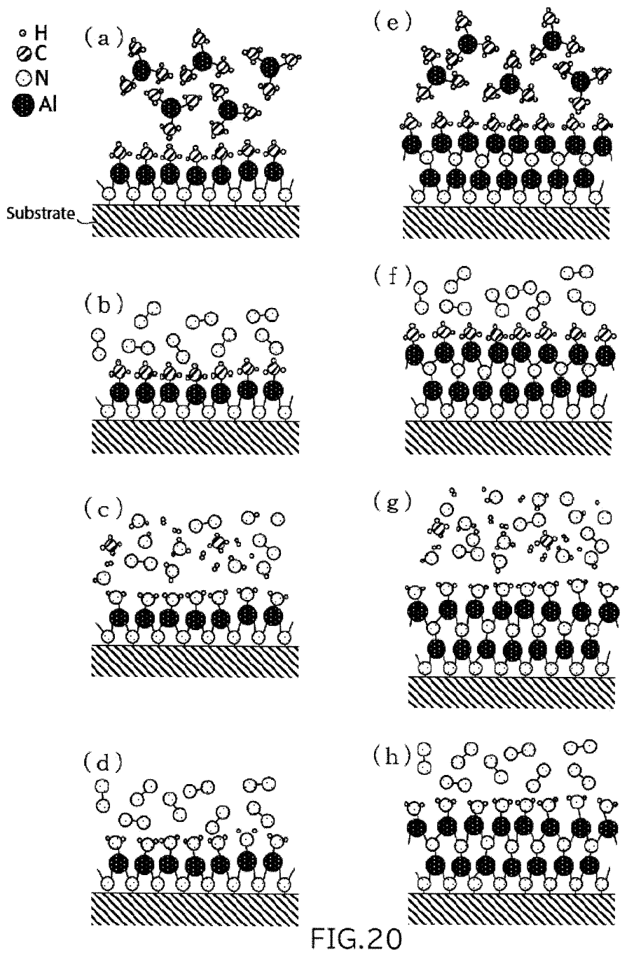

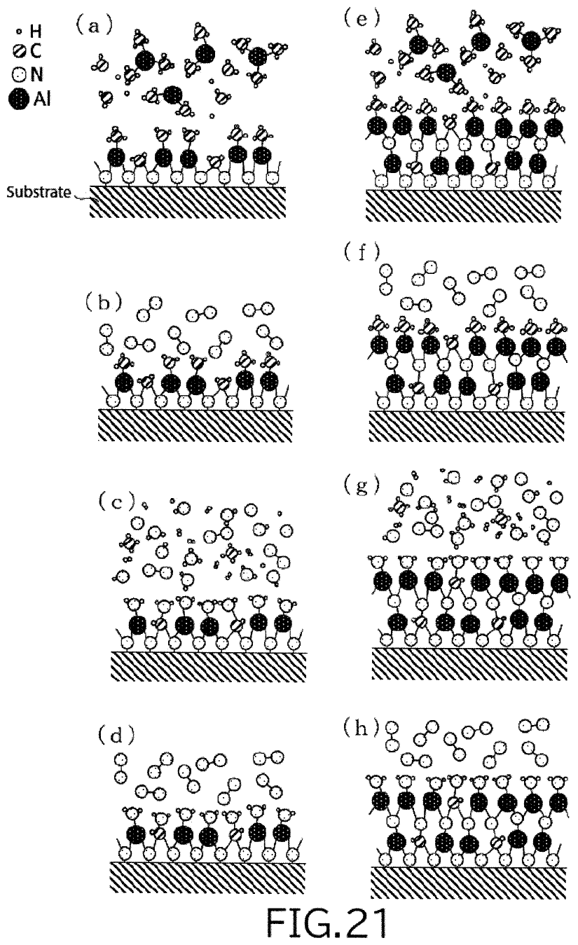

FIGS. 20 and 21 are conceptual diagrams illustrating a configuration of a deposition reaction according to the first embodiment of the present invention, which is described in detail below.

For simplicity, the operation is described for a case in which the preliminary chambers 1 and 2 are used as load lock chambers, and the reactors 3 and 4 and the robot chamber 6 are operated in a vacuum at all times. With the gate 5 between the preliminary chamber 1 or 2 and the robot chamber 6 opened, the substrate 24 is taken out of the preliminary chamber 1 or 2 by the robot 7, and with the gate 5 between the robot chamber 6 and the reactor 3 opened, the substrate 24 is mounted on the spot facing 9 in the reactor 3 through the gate opening 36. In other words, the substrate 24 is moved from outside the reactor 3 and mounted on the spot facings 9 as the substrate mounting portion provided in the reactor 3. At this time, the rotation of the rotary table 18 is to be stopped, and one of the three susceptors 8 is to be positioned in the fourth position. Here, the rotary table 18 is a mechanism that holds a plurality of susceptors 8 so that the spot facings 9 are horizontal and rotates horizontally inside the reactor 3 to arrange the spot facings 9 in the first position, the second position, the third position and the fourth position.

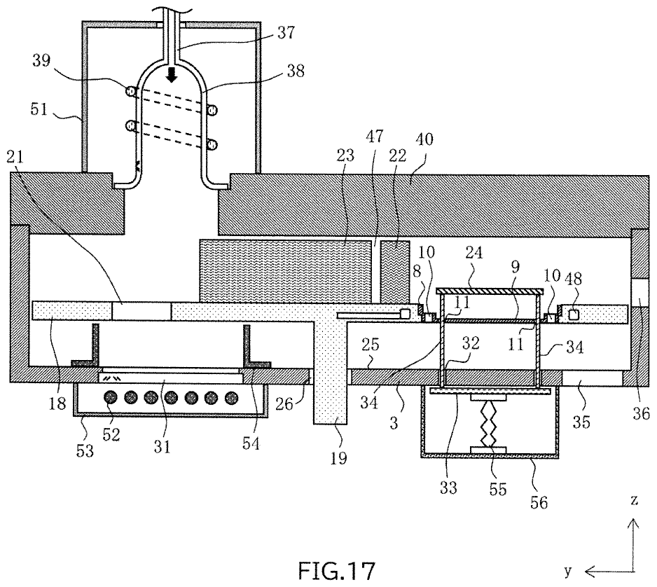

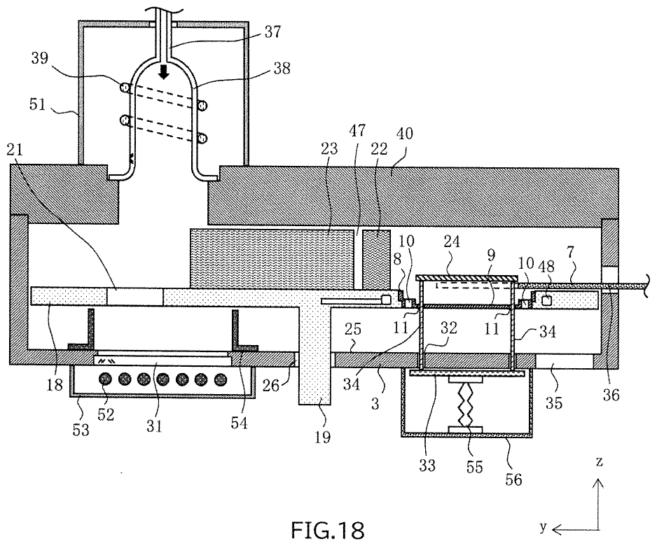

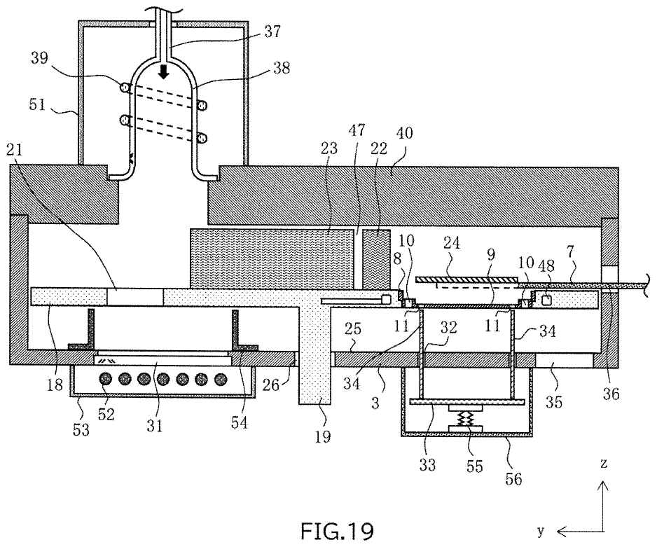

The procedure for exchanging substrates is described here. For easier understanding, an example using the susceptor 8 shown in FIG. 15 is used, in which the four slits 10 are provided beyond the periphery of the spot facing 9 as the gas outlets beyond the periphery of the substrate, and the four pin holes 11 are provided near the edge of the spot facing 9 for guiding the lift pins when transferring a substrate. In FIG. 16, the substrate 24 for which deposition has been finished is mounted on the spot facing 9 on the susceptor 8. At this time, the substrate 24 is positioned in the fourth position where the substrate 24 mounted on the spot facing 9 is to be exchanged with the substrate 24 outside the reactor 3. The fourth position is the position closest to the gate opening 36. Next, as shown in FIG. 17, when the lift pin holder 33 is elevated, the lift pins 34 pass through the pin holes 11 to lift the substrate 24 upward. Then, as shown in FIG. 18, the robot 7 is inserted into the reactor 3 from the robot chamber 6 through the gate opening 36 to move a tip of the robot 7 below the substrate 24. At this time, since the cutout of the circular part of the C-shaped ring 22 is arranged so that it faces outward from the rotary table 18, there is no risk of interference between the robot 7 and the C-shaped ring 22. Next, as shown in FIG. 19, the lift pin holder 33 is lowered to mount the substrate 24 on the tip of the robot 7. After this, the substrate 24 is taken out of the reactor 3 by returning the robot 7 to the robot chamber 6. When transferring the substrate 24 into the reactor 3, an operation is performed in the reverse order of the above.

Next, the rotary table 18 is rotated to mount the substrate 24 on an adjacent spot facing 9. By repeating these operations, the substrates 24 are mounted on all of the spot facings 9 inside the reactor 3. The operation of exchanging substrates, in which the substrates 24 for which the deposition process has been finished are removed from the spot facings 9 and the substrates 24 for which the deposition process has not been performed are mounted on the spot facings 9, may be continuously performed for each of the spot facings 9, or the substrates 24 for which the deposition process has not been performed may be sequentially mounted on the spot facings 9 after all substrates 24 for which the deposition process has been finished inside the reactor 3 are removed from the spot facings 9. While the substrate 24 is being exchanged or mounted, a small amount of purge gas or inert gas is supplied into the reactor 3 from all of the gas nozzles so that a pressure in the reactor 3 is higher than that in the robot chamber 6. This minimizes the concentration of unwanted gases that may enter the reactor 3 from the robot chamber 6 due to the opening of the gate 5.

After the substrates 24 have been mounted on all of the spot facings 9 in the reactor 3, the gate 5 is closed and a small amount of purge gas or inert gas is supplied from all of the gas nozzles into the reactor 3 for a few seconds. This reduces the concentration of unwanted gases that may enter the reactor 3 from the robot chamber 6 due to the opening of the gate 5. Note that noble gases such as Ar or nitrogen (N2) may be used as the purge gas or the inert gas.

Next, an atomic layer deposition process is performed by repeating the steps of rotating the rotary table 18 as well as supplying various gases and operating the lamp unit and the plasma-generating unit. Hereafter, a process flow is described focusing on a single substrate 24.

First, the substrate 24 is sent to the first position (FIG. 10). The first stage 12 is arranged immediately below the position of the substrate 24 in the first position, and the convex portion 13 of the first stage is provided with the temperature control mechanism 50 inside. A temperature of the convex portion 13 is controlled at a temperature suitable for controlling the temperature of the substrate 24 at 50 to 150° C. (100 to 150° C., particularly when TMA is used as the precursor). The temperature of the convex portion 13 may be controlled at approximately +/−10° C. relative to a target temperature of the substrate 24, although conditions depend on process conditions, materials of various components included in the apparatus and other factors. When the inert gas is supplied to the back surface of the susceptor 8 from the first-stage gas nozzle 17, the inert gas is promptly spread over an entire back surface of the susceptor 8 through the grooves 16 that serve as flow paths for the inert gas provided on a surface of the convex portion 13 facing the spot facing 9, causing heat transfer between the back surface of the susceptor 8 and the upper surface of the convex portion 13 to make the temperature of the substrate 24 stabilized at 50 to 150° C. Although noble gases such as Ar or nitrogen (N2) may be used as the inert gas, He, which has a large heat transfer coefficient, promptly minimizes a temperature difference between the susceptor 8 and the convex portion 13. The inert gas does not reach above the rotary table 18 and is mostly exhausted through the gas exhaust ports 35. A vacuum pump, which is not shown in the figure, is connected to a downstream section of the gas exhaust port 35. To prevent the substrate 24 from being lifted or vibrating by supplying the inert gas from below, the purge gas may be supplied through the gas introduction hole 42 at the same time. To ensure the heat transfer between the susceptor 8 and the convex portion 13, the pressure in the reactor 3 is preferably 100 to 1,000 Pa. If the pressure in the reactor 3 is lower than 100 Pa, the heat transfer between the susceptor 8 and the convex portion 13 is insufficient, and conversely, if it exceeds 1000 Pa, it takes time to regulate the pressure to perform an adsorption process for the precursor, which is performed at several hundred Pa.

When the precursor-containing gas is supplied through the gas introduction hole 42, the precursor-containing gas supply manifold 46 is promptly filled with the precursor-containing gas to supply a shower of the precursor-containing gas toward the substrate 24 mounted on the spot facing arranged in the first position. Part of the precursor reacts with a surface of the substrate 24, while a remaining gas flows from the slits 10 to below the rotary table 18 and is exhausted from the gas exhaust ports 35 through the stepped portions 15. Since the slits 10 and the stepped portions 15 are arranged in vertical alignment with each other, unwanted gases are promptly exhausted. The C-shaped rings 22 and the center block 23 effectively prevent the precursor-containing gas from mixing into the second position, the third position and the fourth position. The precursor-containing gas that flows out of the first position in a small amount over the C-shaped rings 22 is discharged from the inter-position gas outlets 21 (the inter-position gas outlet 21 in FIG. 11 and the inter-position gas outlet 21 in FIG. 12) through the gap 47 between the C-shaped rings 22 and the center block 23.

The precursor may be selected as appropriate for a film type to be deposited. For example, TMA (trimethylaluminum) may be used for AlN or Al2O3 deposition, TEMAZ (tetrakis[ethylmethylamino]zirconium) for ZrO2, methylcyclopentadienyl tris(dimethylamino)titanium for TiO2 and 3DMAS (tris[dimethylamino]silane) for SiO2. The precursor is supplied using a bubbler, a vaporizer, an ultrasonic vibrator, an injector, or the like with an amount being controlled at 3 to 30 mg per time, typically 10 mg per time, depending on the process. Since it is difficult to supply the precursor alone to the reactor 3, it is usually diluted with an inert gas such as a noble gas. It is typically diluted with Ar, with a flow rate of a dilution gas ranging approximately from 10 to 1000 sccm (standard cubic centimeters per minute), typically 100 sccm. It is also preferable to heat the dilution gas to prevent the liquefaction of the precursor. A temperature of the dilution gas is approximately 40 to 150° C., typically 80° C. When the substrate 24 is exposed to the precursor-containing gas, precursor molecules are adsorbed on the surface of the substrate 24. The reaction is self-regulating, with an adsorption reaction ending when no more sites are available for adsorption on the surface of the substrate 24. In other words, the surface of the substrate 24 is almost uniformly covered with a thickness of one atomic layer of the precursor molecules adsorbed. FIG. 20 (a) schematically illustrates the reaction when TMA is used for a GaN substrate.

Next, when the purge gas is supplied through the gas introduction hole 42, the precursor-containing gas supply manifold 46 is promptly filled with the purge gas to supply a shower of the purge gas toward the substrate 24 mounted on the spot facing arranged in the first position. At the same time, the precursor remaining near the first position is exhausted from the reactor 3. A flow rate of the purge gas used at this time is approximately 10 to 1000 sccm, typically 100 sccm. FIG. 20 (b) schematically illustrates this reaction.

Then, the rotary table 18 is horizontally rotated 120 degrees to move the substrate 24 to the second position (FIG. 11). When rotating the rotary table 18, a small amount of the purge gas or the inert gas is supplied into the reactor 3 from all of the gas nozzles. The quartz glass window 31 arranged immediately below the position of the substrate 24 in the second position allows the susceptor 8 and the substrate 24 to be heated by the lamp 52 arranged below. Monitoring a temperature of the susceptor 8 or the substrate 24 with a radiation thermometer, or the like, which is not shown in the figure, allows the temperature of the substrate 24 to be controlled at 250 to 700° C. (500 to 700° C., particularly when TMA is used to deposit a nitride film).

When the reactant-containing gas is supplied from the gas inlet 37 in the direction of the arrow, the reactant-containing gas is supplied toward the substrate 24 mounted on the spot facing arranged in the second position. At this time, inductively coupled plasma is generated inside the quartz tube 38 by supplying high-frequency power to the coil 39 and diffuses to the vicinity of the second position. Part of the reactant and some ions and radicals generated by ionization react with the surface of the substrate 24, while the remaining gas flows from the slits 10 to below the rotary table 18 and is exhausted from the gas exhaust ports 35. The C-shaped rings 22 and the center block 23 effectively prevent the reactant-containing gas from mixing into the first position, the third position and the fourth position. The reactant-containing gas that flows out of the first position in a small amount over the C-shaped rings 22 is discharged from the inter-position gas outlets 21 (the inter-position gas outlet 21 in FIG. 10 and the inter-position gas outlet 21 in FIG. 12) through the gap 47 between the C-shaped rings 22 and the center block 23.

The reactant may be selected as appropriate, and H2O, H2O2, ozone, or the like may be used when depositing an oxide film. When depositing a nitride film, a nitriding agent, for example, NH3, may be used. Alternatively, a gas mixture of NH3, H2 and N2 may be used. If the reactant is a liquid substance at room temperature, it is supplied using a bubbler, a vaporizer, an ultrasonic vibrator, an injector, or the like, as in the case of the precursor. For example, when NH3 is used, its amount is controlled at 1 to 100 mg per time, typically 10 mg per time, depending on the process. The reactant may be diluted with an inert gas such as a noble gas. It is typically diluted with Ar, with a flow rate of the dilution gas ranging approximately from 10 to 1000 sccm, typically 100 sccm. The plasma makes the reactant more active and promotes its reaction with the substrate 24. The reaction between the precursor adsorbed on the surface of the substrate 24 and the reactant results in the deposition of a thin film with a thickness of approximately one atomic layer on the surface of the substrate 24. For example, when TMA is used as the precursor and NH3 is used as the reactant, NH3 reacts with methyl groups of the precursor to yield methane (CH4) as a byproduct, which is exhausted out of the reactor 3 through the gas exhaust ports 35, while AlN remains on the surface of the substrate 24 to form a thin film. FIG. 20 (c) schematically illustrates the reaction when TMA is used as the precursor and a gas mixture of NH3, H2 and N2 as the reactant. Here, an N atom on an outermost surface is terminated by two H atoms. In other words, the surface is terminated with amino groups.

Next, when the purge gas is supplied from the gas inlet 37, the purge gas is supplied toward the substrate 24 mounted on the spot facing arranged in the second position. At the same time, the reactant remaining near the second position is exhausted from the reactor 3. FIG. 20 (d) schematically illustrates this reaction.

Then, the rotary table 18 is horizontally rotated 120 degrees to move the substrate 24 to the third position (FIG. 12). The third stage 30 is arranged immediately below the position of the substrate 24 in the third position, and the convex portion 13 of the third stage is provided with the temperature control mechanism 60 inside. The temperature of the convex portion 13 is controlled at a temperature suitable for controlling the temperature of the substrate 24 at a temperature lower than the target temperature of the substrate (for example, 80° C.) in the first position. The temperature of the convex portion 13 may be controlled at approximately +/−10° C. relative to the target temperature of the substrate 24, although the conditions depend on the process conditions, the materials of the various components included in the apparatus and other factors. When the inert gas is supplied to the back surface of the susceptor 8 from the third-stage gas nozzle 57, the inert gas is promptly spread over the entire back surface of the susceptor 8 through the grooves 16 that serve as flow paths for the inert gas provided on the surface of the convex portion 13 facing the spot facing 9, causing the heat transfer between the back surface of the susceptor 8 and the upper surface of the convex portion 13 to make the temperature of the substrate 24 stabilized at, for example, 80° C. Although noble gases such as Ar or nitrogen (N2) may be used as the inert gas, He, which has a large heat transfer coefficient, promptly minimizes the temperature difference between the susceptor 8 and the convex portion 13. The inert gas does not reach above the rotary table 18 and is mostly exhausted through the gas exhaust ports 35. A vacuum pump, which is not shown in the figure, is connected to the downstream section of the gas exhaust port 35. To prevent the substrate 24 from being lifted or vibrating by supplying the inert gas from below, the purge gas may be supplied through the gas introduction hole 43 at the same time. To ensure the heat transfer between the susceptor 8 and the convex portion 13, the pressure in the reactor 3 is preferably 100 to 1,000 Pa. If the pressure in the reactor 3 is lower than 100 Pa, the heat transfer between the susceptor 8 and the convex portion 13 is insufficient, and conversely, if it exceeds 1000 Pa, it takes time to regulate the pressure to perform the adsorption process for the precursor, which is performed at several hundred Pa.

When the purge gas is supplied through the gas introduction hole 43, the purge gas supply manifold 58 is promptly filled with the purge gas to supply a shower of the purge gas toward the substrate 24 mounted on the spot facing arranged in the third position. Supplying the purge gas effectively discharges the reactant-containing gas, which remains near the third position in a small amount, out of the reactor 3. The gas flows from the slits 10 to below the rotary table 18 and is exhausted from the gas exhaust ports 35 through the stepped portions 15. Since the slits 10 and the stepped portions 15 are arranged in vertical alignment with each other, the gas is promptly exhausted. The C-shaped rings 22 and the center block 23 effectively prevent the purge gas from mixing into the first position, the second position and the fourth position. The purge gas that flows out of the third position in a small amount over the C-shaped rings 22 is discharged from the inter-position gas outlets 21 (the inter-position gas outlet 21 in FIG. 10 and the inter-position gas outlet 21 in FIG. 11) through the gap 47 between the C-shaped rings 22 and the center block 23.

Next, the rotary table 18 is horizontally rotated 120 degrees to move the substrate 24 to the first position (FIG. 10). After that, a thin film with a specific thickness can be obtained by repeating a precursor adsorption step and a reactant reaction step described above. FIG. 20 (e) through (h) schematically illustrate a deposition reaction for the second layer. While one deposition cycle is performed on the substrate 24 (while a thin film with a thickness of approximately one atomic layer is formed), in a case of the present embodiment, during one rotation of the substrate 24 in the circumferential direction, the process of exposing each of the substrates 24 to various gases in the order of the precursor-containing gas, the purge gas, the reactant-containing gas, the purge gas and the purge gas occurs only once. To prevent each gas from mixing as much as possible above the rotary table 18, an amount of gas supplied to each position is to be equal so that a difference in pressure between adjacent positions is unlikely to occur. Alternatively, an amount of the purge gas may be slightly larger than that of the precursor-containing gas or the reactant-containing gas. This effectively avoids mixing of the precursor and the reactant in a space including each position.

Thus, rotating the rotary table 18 forms a thin film with a thickness of approximately one atomic layer on the surface of each of the substrates 24. The rotary table 18 may rotate many times inside the reactor 3 and repeatedly perform this series of steps to obtain a thin film with a specific thickness. The expression “approximately one atomic layer” is used here, and since the thickness of a thin film formed in one cycle is approximately 1 to 2 angstroms when converted to a film thickness, for example, a thin film with a thickness of 20 nm needs a process of 100 to 200 cycles, requiring a total of 100 to 200 cycles of rotation of the rotary table 18 in the reactor 3 in the present embodiment.

The substrate 24 for which the deposition of a specific thickness has been finished is taken out of the reactor 3 through the gate opening 36 from the spot facing 9 and stored in the preliminary chamber 1 or 2 using the robot 7, in the reverse order of substrate mounting steps. Two reactors 3 and 4 are provided in the present embodiment, allowing deposition in one of the reactors while exchanging substrates in the other. In this way, time-consuming processes of loading/unloading and film deposition can be simultaneously performed in a plurality of reactors, realizing an atomic layer deposition apparatus and method with higher processing speed and higher area productivity.

For atomic layer deposition, mixing of the precursor and the reactant in a gas phase needs to be suppressed as much as possible to avoid gas-phase reactions. Therefore, the purge gas is preferably always supplied in the third position at the time of supplying the precursor-containing gas or the reactant-containing gas. The purge gas or the reactant-containing gas is preferably always supplied in the second position at the time when the precursor-containing gas is supplied in the first position. The purge gas or the precursor-containing gas is preferably always supplied in the first position at the time when the reactant-containing gas is supplied in the second position. In other words, the precursor-containing gas is not preferred to be supplied in the first position at the time when no gas is being supplied in the second position and the third position, and the reactant-containing gas is not preferred to be supplied in the second position at the time when no gas is being supplied in the first position and the third position.

According to the present embodiment, a higher-quality thin film can be obtained compared to conventional technologies, for example, the atomic layer deposition technologies described in Patent documents 1 through 4. Although a step of reacting the reactant with the substrate requires the temperature of the substrate to be raised to a specific temperature, a step of reacting the precursor with the substrate is also performed similarly at a high temperature in the conventional technologies. This will result in poor film quality because carbon produced by the decomposition of the precursor may be incorporated into the film. FIG. 21 schematically illustrates the evolution of this reaction. In FIG. 21 (a), the temperature of the substrate higher than 150° C. may cause the decomposition of TMA in the gas phase. The decomposition of TMA yields radicals such as CH3 and CH2, with some carbon atoms being incorporated into an adsorbed layer. In FIG. 21 (b), carbon atoms remain in the film even when the gas is replaced with the purge gas. In FIG. 21 (c), when the substrate is exposed to the reactant-containing gas, the surface of the substrate is terminated with amino groups. In FIG. 21 (d), the gas is replaced again with the purge gas. FIG. 21 (e) through (h) schematically illustrate the deposition reaction for the second layer, and in FIG. 21 (e), when the substrate is exposed again to the precursor-containing gas, some carbon atoms are incorporated into the adsorbed layer. In this way, the temperature of the substrate higher than 150° C. during the precursor adsorption step is assumed to deteriorate film properties due to the incorporation of unwanted carbon in the film. In contrast, in the present embodiment, no decomposition of TMA occurs in the gas phase during a step of supplying the precursor-containing gas, allowing a good-quality thin film with almost no carbon in the film to be obtained, as described with reference to FIG. 20. In the step of supplying the precursor-containing gas, the temperature of the substrate is preferably 50° C. or higher. The temperature of the substrate lower than 50° C. hinders the migration of the precursor on the substrate, making it difficult to obtain a well-structured adsorbed layer. Since a decomposition temperature depends on a type of the precursor applicable to the film type to be deposited (oxide film, nitride film, or the like), the temperature is preferably controlled at a suitable temperature.

A higher temperature of the substrate in a step of exposing it to the reactant-containing gas generally results in a dense, good-quality thin film. Therefore, a second temperature in the step of exposing the substrate to the reactant-containing gas is preferably higher than the first temperature in a step of exposing it to the precursor-containing gas. The second temperature for forming an AlN thin film using TMA is preferably 250° C. or higher. Since the temperature of the substrate higher than 700° C. poses difficulties in terms of apparatus configuration, such as restrictions on component materials to avoid deformation and degradation, the temperature of the substrate is preferably 250 to 700° C.

According to the present embodiment, unlike the film deposition apparatus described in the conventional technologies, for example, in Patent document 1, supplying the inert gas to the back surface of the substrate 24 in the first position prevents the precursor from being adsorbed on the back surface of the substrate 24, resulting in no thin film formation. This provides the advantage of eliminating the need for an additional process of etching the back surface.

In the present embodiment, the spot facing 9 and the convex portion 13 of the first stage or the third stage are in close proximity to each other. This ensures effective heat transfer between the spot facing 9 and the first stage or the third stage. To obtain such an effect, a distance between the spot facing 9 and the convex portion 13 of the first stage or the third stage is preferably 0.5 mm or greater and 2 mm or smaller. If the distance between the spot facing 9 and the convex portion 13 of the first stage or the third stage is shorter than 0.5 mm, the spot facing 9 and the convex portion 13 of the first stage or the third stage may be in contact when a rotation accuracy deteriorates due to aging of the apparatus or other factors. Conversely, if the distance between the spot facing 9 and the convex portion 13 of the first stage or the third stage is wider than 2 mm, heat transfer efficiency decreases extremely.

In the present embodiment, the C-shaped rings 22 and the center block 23 are arranged on the rotary table 18, the upper surfaces of which are in close proximity to the ceiling surface of the reactor 3. This effectively suppresses the mixing of gases between adjacent positions. The precursor-containing gas that flows out of the first position in a small amount over the C-shaped rings 22 is discharged from the inter-position gas outlets 21 through the gap 47 between the C-shaped rings 22 and the center block 23. To obtain such an effect, a distance between uppermost portions of the C-shaped rings 22 and the center block 23, and the ceiling surface (upper inner wall) of the reactor 3 is preferably 0.5 mm or greater and 10 mm or smaller. If the distance between the uppermost portions of the C-shaped rings 22 and the center block 23, and the ceiling surface (upper inner wall) of the reactor 3 is smaller than 0.5 mm, the uppermost portions of the C-shaped rings 22 and the center block 23 may be in contact with the ceiling surface (upper inner wall) of the reactor 3 when the rotation accuracy deteriorates due to the aging of the apparatus or other factors. Conversely, if the distance between the uppermost portions of the C-shaped rings 22 and the center block 23, and the ceiling surface (upper inner wall) of the reactor 3 is wider than 10 mm, a risk of mixing of the precursor-containing gas and the reactant-containing gas is slightly higher.

### Second Embodiment

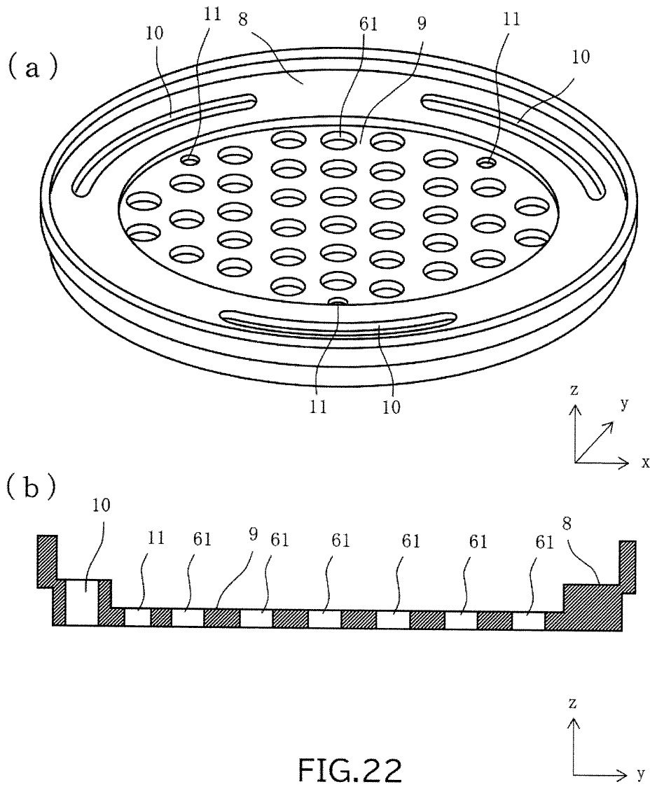

The following is a description of a second embodiment of the present invention with reference to FIG. 22.

FIG. 22 is a perspective view (a) and a cross-sectional view (b) of the configuration of the susceptor according to the second embodiment of the present invention, showing the state in which the substrate is not mounted on the susceptor. FIG. 22 (b) is a cross-sectional view of FIG. 22 (a) when cut along a plane parallel to the yz-plane that includes the center of the susceptor.

In FIG. 22, the overall shape of the susceptor 8 is similar to that of the substrate (circular) and is provided with the spot facing 9 that is circular in shape as the substrate mounting portion. Three slits 10 are provided beyond the periphery of the spot facing 9 as the gas outlets beyond the periphery of the substrate, and three pin holes 11 are provided near the edge of the spot facing 9 for guiding the lift pins when transferring a substrate. Both the slits 10 and the pin holes 11 are arranged at equal intervals along the circumferential direction. In addition, numerous through holes 61 are provided over the entire surface of the spot facing 9. This configuration promotes heat transfer between the substrate 24 and the first stage or the third stage and accelerates lamp heating in the second position, enabling higher productivity for atomic layer deposition.

### Third Embodiment

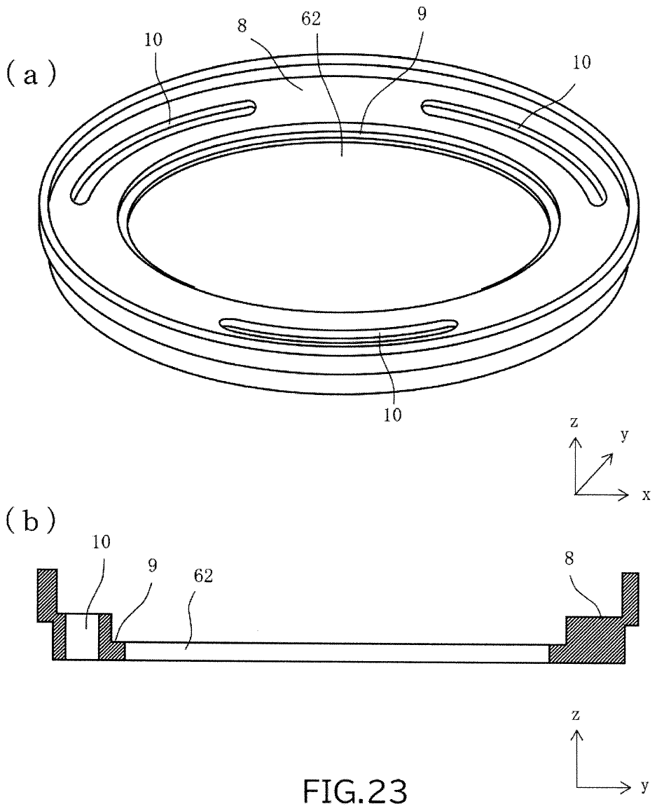

The following is a description of a third embodiment of the present invention with reference to FIG. 23.

FIG. 23 is a perspective view (a) and a cross-sectional view (b) of the configuration of the susceptor according to the third embodiment of the present invention, showing the state in which the substrate is not mounted on the susceptor. FIG. 23 (b) is a cross-sectional view of FIG. 23 (a) when cut along a plane parallel to the yz-plane that includes the center of the susceptor.

In FIG. 23, the overall shape of the susceptor 8 is similar to that of the substrate (circular) and is provided with the spot facing 9 that is circular in shape as the substrate mounting portion. Three slits 10 are provided beyond the periphery of the spot facing 9 as the gas outlets beyond the periphery of the substrate, and three pin holes 11 are provided near the edge of the spot facing 9 for guiding the lift pins when transferring a substrate. Both the slits 10 and the pin holes 11 are arranged at equal intervals along the circumferential direction. In addition, one through hole 62 is provided over the entire surface of the spot facing 9. This configuration promotes heat transfer between the substrate 24 and the first stage or the third stage and accelerates lamp heating in the second position, enabling higher productivity for atomic layer deposition.

### Fourth Embodiment

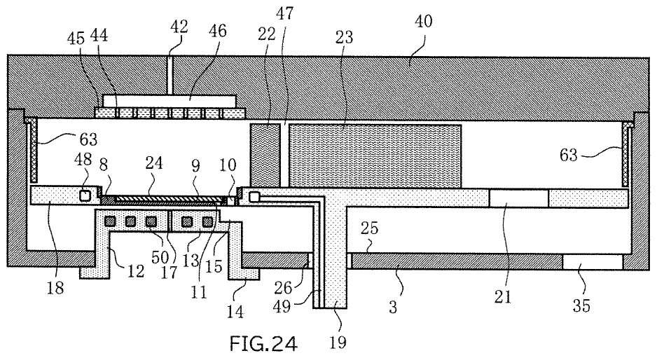

The following is a description of a fourth embodiment of the present invention with reference to FIG. 24.

FIG. 24 is a cross-sectional view illustrating the configuration of the reactor according to the fourth embodiment of the present invention, which corresponds to FIG. 10.

In FIG. 24, an inner cover 63 is provided to cover a side wall surface of the reactor 3. Although the present invention takes various measures to suppress the mixing of the precursor and the reactant, long-term operation of the apparatus may result in the deposition of a thin film, though in a very small amount, also on the side wall surfaces of the reactor 3. Thus, operating the apparatus with the side wall surface of the reactor 3 protected by the inner cover 63, and periodically removing and cleaning the inner cover 63 enables the inner surface of the reactor 3 to always be kept clean. Note that the inner cover 63 is provided with a through hole near the fourth position, which is not shown in the figure, with a sufficient penetrating area for the substrate and the robot 7 to pass through for exchanging the substrates.

The atomic layer deposition apparatus and method described above are merely typical examples of the scope of application of the present invention, and the invention can be applied to various other fields in addition to those described above.

For example, although the example illustrates an apparatus provided with three exhaust ports, pipes may be joined at the downstream section of the exhaust ports to exhaust the reactor 3 with one vacuum pump, or each exhaust port may be exhausted with a separate pump. Alternatively, a separate pressure regulator valve may be used for each exhaust port to finely control the pressure. Needless to say, the number of exhaust ports is not limited to three.

Although the example illustrates an apparatus provided with the third position to lower the temperature of the substrate 24, the first position may serve as the function of the third position without using the third position. The use of the third position has the advantage of enabling faster processing since another substrate can be cooled while performing adsorption and nitridation reactions.

Although the example illustrates an apparatus that exchanges substrates in the fourth position, the substrates may be exchanged in the first, second or third position without including the fourth position. To exchange substrates in the first or third position, a mechanism for lift pins needs to be incorporated below the first stage 12 or the third stage 30, increasing design restrictions. Similarly, to exchange substrates in the second position, the mechanism for lift pins needs to be incorporated below the lamp unit, making the design very difficult. Therefore, the fourth position for exchanging substrates is preferably provided in addition to the first, second and third positions.

Although the example illustrates an apparatus provided with a plasma-generating unit that generates plasma in the second position, the atomic layer deposition process may be performed with the second position in the same configuration as the first position without using the plasma-generating unit.

Although the example illustrates an apparatus that generates inductively coupled plasma in the quartz tube 38 by supplying high-frequency power to the coil 39 as a plasma-generating unit, various methods of generating plasma, such as a method using electrodes, pulsed power or a microwave, may also be applied. The plasma-generating unit is preferably provided in an upper stream of gas flow than the substrate mounting surface. This makes the use of active particles, such as ions and radicals, more efficient.

The various configurations of the present invention enable various film deposition processes. For example, it is effective to apply them to the manufacturing of electronic devices such as semiconductors, flat panel displays, solar cells and light-emitting diodes. It is especially useful for AlN formation for GaN power semiconductor devices. It can be used in many processes, including the double patterning process, high-k/metal gate formation, top and bottom electrode formation for DRAM capacitors using TiN or Ru, gate electrode sidewall formation using SiN and barrier seed formation in contact holes and through holes for semiconductor integrated circuit manufacturing, as well as high-k dielectric and charge trap film formation for a NAND flash memory. It can also be used in the formation of ITO films and passivation films for flat panel displays, LEDs and solar cells.

### INDUSTRIAL APPLICABILITY

As described above, the present invention can be used to manufacture various electronic devices and is effective to be applied to the manufacturing of electronic devices such as semiconductors, flat panel displays, solar cells and light-emitting diodes. It is especially useful for AIN formation for GaN power semiconductor devices. It can be used in many processes, including the double patterning process, high-k/metal gate formation, top and bottom electrode formation for DRAM capacitors using TiN or Ru, gate electrode sidewall formation using SiN and barrier seed formation in contact holes and through holes for semiconductor integrated circuit manufacturing, as well as high-k dielectric and charge trap film formation for a NAND flash memory. The present invention is also useful in the formation of ITO films and passivation films for flat panel displays, LEDs and solar cells.

### Reference Signs List

3 reactor
8 susceptor
9 spot facing
10 slit
11 pin hole
13 convex portion
14 bottom portion
15 stepped portion
18 rotary table
19 shaft
21 inter-position gas outlet
22 C-shaped ring
23 center block
24 substrate
26 shaft hole
30 third stage
35 gas exhaust port
40 lid
43 gas introduction hole
44 shower hole
45 shower plate
47 gap
48 refrigerant flow path
57 third-stage gas nozzle
58 purge gas supply manifold

What is claimed is:

1. An atomic layer deposition apparatus comprising:
a reactor;
a plurality of susceptors each provided with a substrate mounting portion;
a first position that controls a temperature of a substrate mounted on the substrate mounting portion at a first temperature;
a second position that controls the temperature of a substrate mounted on the substrate mounting portion at a second temperature;
a precursor nozzle that supplies a precursor-containing gas to the substrate mounting portion arranged in the first position;
a reactant nozzle that supplies a reactant-containing gas to the substrate mounting portion arranged in the second position; and
a rotary table that mounts the plurality of susceptors so that the substrate mounting portions are horizontal and rotates horizontally inside the reactor to arrange the substrate mounting portions in the first position and the second position,
wherein the first temperature is 50 to 150° C., the second temperature is 250 to 700° C., and the second temperature is higher than the first temperature.

2. An atomic layer deposition apparatus comprising:
a reactor;
a plurality of susceptors each provided with a substrate mounting portion;
a first position that controls a temperature of a substrate mounted on the substrate mounting portion at a first temperature;
a second position that controls the temperature of a substrate mounted on the substrate mounting portion at a second temperature;
a precursor nozzle that supplies a precursor-containing gas to the substrate mounting portion arranged in the first position;
a reactant nozzle that supplies a reactant-containing gas to the substrate mounting portion arranged in the second position; and
a rotary table that mounts the plurality of susceptors so that the substrate mounting portions are horizontal and rotates horizontally inside the reactor to arrange the substrate mounting portions in the first position and the second position,
further comprising a third position that controls the temperature of a substrate mounted on the substrate mounting portion at a third temperature,
wherein the second temperature is higher than the first temperature, and
wherein the third temperature is lower than the first temperature.

3. An atomic layer deposition apparatus comprising:
a reactor;
a plurality of susceptors each provided with a substrate mounting portion;
a first position that controls a temperature of a substrate mounted on the substrate mounting portion at a first temperature;
a second position that controls the temperature of a substrate mounted on the substrate mounting portion at a second temperature;
a precursor nozzle that supplies a precursor-containing gas to the substrate mounting portion arranged in the first position;
a reactant nozzle that supplies a reactant-containing gas to the substrate mounting portion arranged in the second position; and
a rotary table that mounts the plurality of susceptors so that the substrate mounting portions are horizontal and rotates horizontally inside the reactor to arrange the substrate mounting portions in the first position and the second position,
further comprising a plasma-generating unit above the second position,
wherein the second temperature is higher than the first temperature.

4. An atomic layer deposition apparatus comprising:
a reactor;
a plurality of susceptors each provided with a substrate mounting portion;
a first position that controls a temperature of a substrate mounted on the substrate mounting portion at a first temperature;
a second position that controls the temperature of a substrate mounted on the substrate mounting portion at a second temperature;
a precursor nozzle that supplies a precursor-containing gas to the substrate mounting portion arranged in the first position;
a reactant nozzle that supplies a reactant-containing gas to the substrate mounting portion arranged in the second position; and
a rotary table that mounts the plurality of susceptors so that the substrate mounting portions are horizontal and rotates horizontally inside the reactor to arrange the substrate mounting portions in the first position and the second position,
further comprising: a first stage in close proximity to the substrate mounting portion in the first position;
a temperature control mechanism that controls the first stage at a specific temperature;
a third position that controls the temperature of a substrate mounted on the substrate mounting portion at a third temperature;
a third stage in close proximity to the substrate mounting portion in the third position; and
a temperature control mechanism that controls the third stage at
a specific temperature,
wherein the second temperature is higher than the first temperature.

5. The atomic layer deposition apparatus according to claim 4, further comprising: a first-stage gas nozzle that supplies an inert gas from below the first stage between the substrate mounting portion and the first stage in the first position; and
a third-stage gas nozzle that supplies an inert gas from below the third stage between the substrate mounting portion and the third stage in the third position.

6. The atomic layer deposition apparatus according to claim 5, wherein a groove that serves as a flow path for the inert gas is provided on each surface of the first stage and the third stage that faces the substrate mounting portion.

7. An atomic layer deposition apparatus comprising:
a reactor;
a plurality of susceptors each provided with a substrate mounting portion;
a first position that controls a temperature of a substrate mounted on the substrate mounting portion at a first temperature;
a second position that controls the temperature of a substrate mounted on the substrate mounting portion at a second temperature;
a precursor nozzle that supplies a precursor-containing gas to the substrate mounting portion arranged in the first position;
a reactant nozzle that supplies a reactant-containing gas to the substrate mounting portion arranged in the second position; and
a rotary table that mounts the plurality of susceptors so that the substrate mounting portions are horizontal and rotates horizontally inside the reactor to arrange the substrate mounting portions in the first position and the second position,
wherein a plurality of C-shaped rings that each form a horseshoe shape as a whole and are each composed of a circular ring having a cutout are arranged on the rotary table concentrically with the substrate mounting portions in the first position and the second position,
wherein upper surfaces of the plurality of C-shaped rings are in close proximity to a ceiling surface of the reactor, and
wherein the second temperature is higher than the first temperature.

8. The atomic layer deposition apparatus according to claim 7, further comprising a center block that fills a space between the plurality of C-shaped rings while providing a gap with respect to the plurality of C-shaped rings,
wherein an upper surface of the center block is in close proximity to the ceiling surface of the reactor.

9. The atomic layer deposition apparatus according to claim 8, further comprising an inter-position gas outlet on the rotary table outside of the center block.

10. The atomic layer deposition apparatus according to claim 7, further comprising a substrate peripheral portion gas outlet between the substrate mounting portion and the C-shaped ring.

11. An atomic layer deposition method, in a reactor comprising: a first position that controls a temperature of a substrate mounted on a substrate mounting portion that is horizontally arranged at a first temperature; and
a second position that controls the temperature of a substrate mounted on the substrate mounting portion at a second temperature,
the atomic layer deposition method comprising:
a step of moving a substrate from outside the reactor and mounting it on the substrate mounting portion;
a step of supplying a precursor-containing gas to the substrate mounting portion arranged in the first position and supplying a reactant-containing gas to the substrate mounting portion arranged in the second position while exhausting the reactor; and
a step of rotating a rotary table that arranges the substrate mounting portions in the first position and the second position horizontally inside the reactor,
wherein the first temperature is 50 to 150° C. and the second temperature is 250 to 700° C., and
wherein the second temperature is higher than the first temperature.

12. An atomic layer deposition method, in a reactor comprising: a first position that controls a temperature of a substrate mounted on a substrate mounting portion that is horizontally arranged at a first temperature; and
a second position that controls the temperature of a substrate mounted on the substrate mounting portion at a second temperature,
the atomic layer deposition method comprising:
a step of moving a substrate from outside the reactor and mounting it on the substrate mounting portion;
a step of supplying a precursor-containing gas to the substrate mounting portion arranged in the first position and supplying a reactant-containing gas to the substrate mounting portion arranged in the second position while exhausting the reactor; and
a step of rotating a rotary table that arranges the substrate mounting portions in the first position and the second position horizontally inside the reactor,
further comprising a step of mounting a substrate in a third position that controls the temperature of the substrate at a third temperature lower than the first temperature,
wherein the second temperature is higher than the first temperature.

13. An atomic layer deposition method, in a reactor comprising: a first position that controls a temperature of a substrate mounted on a substrate mounting portion that is horizontally arranged at a first temperature; and
a second position that controls the temperature of a substrate mounted on the substrate mounting portion at a second temperature,
the atomic layer deposition method comprising:
a step of moving a substrate from outside the reactor and mounting it on the substrate mounting portion;
a step of supplying a precursor-containing gas to the substrate mounting portion arranged in the first position and supplying a reactant-containing gas to the substrate mounting portion arranged in the second position while exhausting the reactor; and
a step of rotating a rotary table that arranges the substrate mounting portions in the first position and the second position horizontally inside the reactor,
further comprising a step of generating plasma from a reactant-containing gas by means of a plasma-generating unit provided above the second position,
wherein the second temperature is higher than the first temperature.

14. An atomic layer deposition method, in a reactor comprising: a first position that controls a temperature of a substrate mounted on a substrate mounting portion that is horizontally arranged at a first temperature; and
a second position that controls the temperature of a substrate mounted on the substrate mounting portion at a second temperature,
the atomic layer deposition method comprising:
a step of moving a substrate from outside the reactor and mounting it on the substrate mounting portion;
a step of supplying a precursor-containing gas to the substrate mounting portion arranged in the first position and supplying a reactant-containing gas to the substrate mounting portion arranged in the second position while exhausting the reactor; and
a step of rotating a rotary table that arranges the substrate mounting portions in the first position and the second position horizontally inside the reactor,
further comprising: a step of arranging a substrate in a third position that controls the temperature of the substrate at a third temperature lower than the first temperature;
a step of controlling the temperature of the substrate at the first temperature using a first stage provided in the first position in close proximity to the substrate mounting portion and a temperature control mechanism that controls the first stage at a specific temperature; and
a step of controlling the temperature of the substrate at the third temperature using a third stage provided in the third position in close proximity to the substrate mounting portion and a temperature control mechanism that controls the third stage at a specific temperature,
wherein the second temperature is higher than the first temperature.

15. An atomic layer deposition method, in a reactor comprising: a first position that controls a temperature of a substrate mounted on a substrate mounting portion that is horizontally arranged at a first temperature; and
a second position that controls the temperature of a substrate mounted on the substrate mounting portion at a second temperature,
the atomic layer deposition method comprising:
a step of moving a substrate from outside the reactor and mounting it on the substrate mounting portion;
a step of supplying a precursor-containing gas to the substrate mounting portion arranged in the first position and supplying a reactant-containing gas to the substrate mounting portion arranged in the second position while exhausting the reactor; and
a step of rotating a rotary table that arranges the substrate mounting portions in the first position and the second position horizontally inside the reactor,
wherein a plurality of C-shaped rings that each form a horseshoe shape as a whole and are each composed of a circular ring having a cutout are arranged on the rotary table concentrically with the substrate mounting portions in the first position and the second position,
wherein upper surfaces of the plurality of C-shaped rings are in close proximity to a ceiling surface of the reactor, and wherein the second temperature is higher than the first temperature.
